(19) United States
(12) Patent Application Publication
(10) Pub. No.: US 2025/0079285 A1
(43) Pub. Date: Mar. 6, 2025

(54) POWER MODULE

(71) Applicants: Hyundai Motor Company, Seoul (KR); Kia Corporation, Seoul (KR)

(72) Inventors: Jin Myeong YANG, Seongnam-si (KR); Sung Won PARK, Incheon (KR); Han Jin DO, Incheon (KR)

(21) Appl. No.: 18/613,005

(22) Filed: Mar. 21, 2024

(30) Foreign Application Priority Data
Sep. 4, 2023 (KR) 10-2023-0117082
Dec. 27, 2023 (KR) 10-2023-0193432

(51) Int. Cl. H01L 23/498; H01L 23/31; H01L 23/64; H01L 25/065

(52) U.S. Cl. CPC H01L 23/49838; H01L 23/3121; H01L 23/647; H01L 25/0655

(57) ABSTRACT

A power module includes at least one semiconductor chip, at least one substrate that supports the at least one semiconductor chip, and a first lead. The first lead includes (i) an extended portion having a first end connected to the at least one substrate and a second end protruding outward away from the at least one substrate and (ii) a resistance portion disposed between the first end and the second end of the extended portion.

### CROSS REFERENCE TO RELATED APPLICATIONS

The present application claims priority to Korean Patent Application No. 10-2023-0117082, filed on Sep. 4, 2023, and Korean Patent Application No. 10-2023-0193432, filed on Dec. 27, 2023, the entire contents of which are incorporated herein for all purposes by this reference.

### TECHNICAL FIELD

The present disclosure relates to a power module with an output terminal-integrated current sensor structure.

### BACKGROUND

With the growing interest in the environment, there is a trend of increasing eco-friendly vehicles equipped with electric motors as power sources. Eco-friendly vehicles, also known as electrified vehicles, include electric vehicles (EVs) and hybrid electric vehicles (HEVs).

In electrified vehicles, an inverter is typically equipped to convert direct current power to alternating current power for motor operation, and the inverter is usually composed of one or multiple power modules incorporating semiconductor chips that perform switching functions.

To control the power conversion system of a vehicle that includes a power module, it is necessary to sense the current of the power module, which can be achieved by either equipping an external current sensor or incorporating resistive elements like shunt resistors inside the power module.

### SUMMARY

It is an object of the present disclosure to provide a power module capable of securing space for current sensing, reducing costs, and enhancing the accuracy of current sensing by allowing a current sensor implemented through the output terminal to sense the current of the power module.

The objects of the present disclosure are not limited to the aforesaid, and other objects not described herein will be clearly understood by those skilled in the art from the descriptions below.

In order to accomplish the above objects, a power module includes at least one semiconductor chip, at least one substrate on which the at least one semiconductor chip is mounted, and a first lead including an extended portion connected at one end to the at least one substrate and extending at the other end to protrude outward from the at least one substrate and a resistance portion disposed between the one end and the other end.

For example, the first lead may electrically connect the substrate to an external terminal by connecting the other end of the extended portion to the external terminal.

For example, the first lead may form a current flow path from the substrate to the external terminal.

For example, the first lead may form a current flow path in the direction from one end of the extended portion to the other end of the extended portion via the resistance portion.

For example, the resistance portion may extend in a direction crossing the direction in which the extended portion is extended.

For example, the one end and the other end of the extended portion may be connected via the resistance portion.

For example, the one end and the other end of the extended portion may be connected to opposite ends of the resistance portion in the direction in which the extended portion extends.

For example, a power module may further include a connector connected to the resistance portion to output voltage across both ends of the resistance portion.

For example, the connector may be connected to the resistance portion, elongating along the direction from one end to the other end of the extended portion, with the resistance portion being positioned between one end and the other end of the connector.

For example, the connector may include terminals and a cover covering the terminals in predetermined directions, the terminals including a plurality of first terminals respectively outputting voltage at both ends of the resistance portion.

For example, the terminals may be connected to an external control board.

For example, the terminals may include a second terminal grounded to the external control board.

For example, the power module may further include a plurality of second leads connected to the at least one substrate and separated from the first lead.

For example, the first lead may receive the current inflow from at least one of the plurality of second leads through the substrate and one end of the extended portion.

For example, the power module may further include a molding member encasing the at least one semiconductor chip and one end of the extended portion.

For example, the at least one substrate may include a first substrate and a second substrate spaced apart with the semiconductor chip disposed therebetween, and one end of the first lead may be placed between the first and second substrates.

As described above, the power module in various implementations of the present disclosure is advantageous in terms of reducing the interior space required for the current sensing through implementation of a current sensor structure on its output terminal.

With the reduction in the space required for sensing, it becomes possible to secure component layout space inside the power module, allowing for an increase in the size of each component, leading to an enhancement in the performance of the power module.

In addition, by securing space for current sensing, it becomes possible to sense current without relying on an external current sensor, thus eliminating incurrence of the cost associated with the placement of external current sensors.

Furthermore, it is possible to improve the current sensing performance by sensing the current immediately before the current is output from the power module.

The advantages of the present disclosure are not limited to the aforesaid, and other advantages not described herein may be clearly understood by those skilled in the art from the descriptions below.

### BRIEF DESCRIPTION OF THE DRAWINGS

FIG. 1 is a diagram illustrating an example of a power module.

FIG. 2 is a diagram illustrating an example of a first lead.

FIG. 3 is a diagram illustrating an example of a connector.

### DETAILED DESCRIPTION

Hereinafter, descriptions are made of the implementations disclosed in the present specification with reference to the accompanying drawings in which the same reference numbers are assigned to refer to the same or like components and redundant description thereof is omitted.

In some implementations, a power module is proposed to have an output terminal-integrated current sensor structure, thereby securing space for the current sensor and improving sensing performance.

For example, a power module is proposed to have a structure capable of performing current sensing while reducing the separate space required for the current sensor placement within the power module, compared to the case where the current sensor is mounted within the power module. In some examples, the current sensor can be placed on the board of the power module.

In some implementations, a power module is proposed to have a structure capable of reducing the size and costs compared to the case where a separate external current sensor is mounted outside the power module.

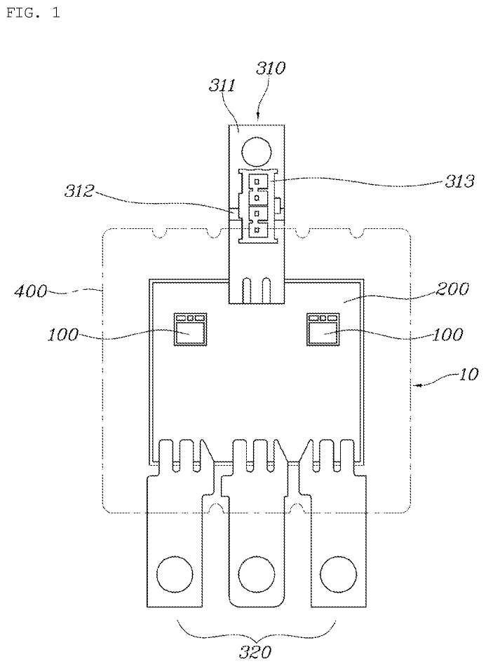

Hereinafter, a description is made of the power module according to one or more implementations of the present disclosure in detail with reference to FIGS. 1 to 3.

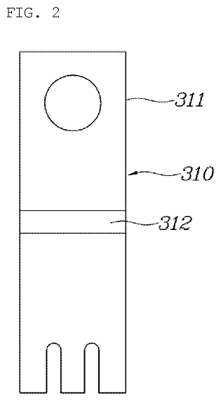

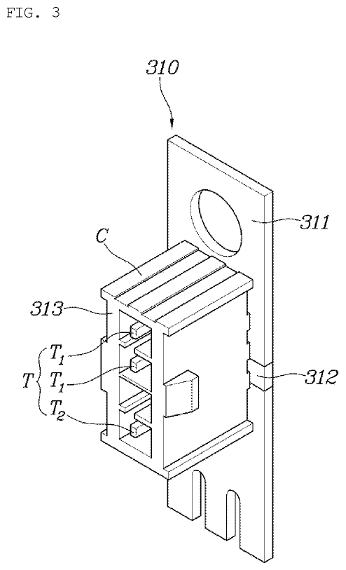

FIG. 1 is a diagram illustrating an example of a power module, FIG. 2 is a diagram illustrating an example of a first lead, and FIG. 3 is a diagram illustrating an example of a connector.

In some implementations, with reference to FIG. 1, the power module 10 may include at least one semiconductor chip 100, at least one substrate 200, a first lead 310, a plurality of second leads 320, and a molding member 400. However, it should be noted that FIG. 1 only shows the components essential to the description of an implementation of the present disclosure, and the actual power module may be implemented with more or fewer components. The following is a detailed explanation of the individual components of the power module according to the implementations of the present disclosure.

In some implementations, the at least one semiconductor chip 100 may be mounted on at least one substrate 200 and may be electrically connected to the at least one substrate 200. In more detail, the semiconductor chip 100 may be bonded to the substrate 200 by soldering or sintering, and a separate component such as a spacer may be used for the connection with the substrate 200.

In some examples, the semiconductor chip 100 may be turned on/off based on switching signals, and the conduction between the upper and lower sides of the semiconductor chip 100 may be determined based on its on/off state.

For example, the semiconductor chips 100 may be implemented as switching devices such as insulated gate bipolar transistors (IGBT) or metal-oxide-semiconductor field-effect transistors (MOSFET), and they may be made of silicon or silicon carbide.

In some examples, the at least one substrate 200 may be made by stacking a plurality of layers including an insulating layers and metal layers.

For example, the substrate 200 may be formed by stacking an insulating layer and a metal layer arranged on the surface facing the interior of the power module 10. In this case, the insulating layer may electrically isolate the inside and outside of the power module, while the metal layer facing the inside of the power module may form electrical connections within the power module.

To improve cooling efficiency, a metal layer may also be arranged on the surface of the insulating layer facing the exterior of the power module, and these metal layers may facilitate heat dissipation from the interior of the power module, especially from the semiconductor chips 100, through heat exchange with the exterior, thus cooling the power module.

The insulating layer may be made of materials like ceramics, while the metal layer may be made of materials like copper. In this case, the at least one substrate 200 may be implemented using methods such as active metal brazing (AMB) or direct bonded copper (DBC).

In some examples, the power module may have a structure in which the semiconductor chip 100 is mounted on a single substrate 200. In some examples, the power module may have a structure in which the semiconductor chip 100 is mounted between a plurality of substrates 200. In the former case, heat generated in the semiconductor chip 100 may be dissipated in one direction through a single substrate 200, utilizing a one-sided cooling method, while in the latter case, heat generated in the semiconductor chip 100 may be dissipated in both directions through two substrates 200, utilizing a dual-sided cooling method.

In the case where the power module 10 is implemented with a dual-sided cooling method in which the semiconductor chip 100 is mounted between a plurality of substrates 200 as mentioned earlier, the plurality of substrates 200 spaced apart and arranged around the semiconductor chip 100 may be referred to as the first substrate and the second substrate, respectively, and in this case, the first lead 310 may have an extended portion 311 of which one end is placed between the first substrate and the second substrate.

In some examples, with reference to FIGS. 1 and 2, the first lead 310 may include the extended portion 311 connected at one end to the at least one substrate 200 and extending at the other end to protrude outward from the at least one substrate 200 and a resistance portion disposed between the one end and the other end of the extended portion 311.

The other end of the extended portion 311 of the first lead 310 may be connected to an external terminal, thereby electrically connecting the substrate 200 to an external terminal, and in particular, forming a current path from the substrate 200 to the external terminal.

In more detail, the first lead 310 may form a current path in the direction from the one end of the extended portion 311, through the resistance portion 312, and to the other end of the extended portion 311.

Through this current path, the current flowing from the interior of the power module 10 to the external terminal passes through the resistance portion 312, and the voltage across both ends of the resistance portion 312. For example, the voltage may be used to sense the output current of the power module 10.

To achieve this, the resistance portion 312 may extend in a direction crossing the direction in which the extended portion 311 is extended. That is, the resistance portion 312 may be implemented in a direction that crosses the extended portion 311.

In this case, the one end and the other end of the extended portion 311 may be connected to through the resistance portion 312. For instance, the first lead 310 may include three parts, connected in order, of the one end of the extended portion 311, the resistance portion 312, and the other end of the extended portion 311.

The extended portion 311 and the resistance portion 312 may have the same width and thickness, which allows the entire current passing through the cross-section of the one end of the extended portion 311 to pass through the cross-section of the resistance portion 312 and then be output along the cross-section of the other end of the extended portion 311.

In some examples, with reference to FIGS. 1 and 3, a connector 313 may be connected to the resistance portion 312 to output the voltage across both ends of the resistance portion 312, and the ends of the resistance portion 312 may be distinguished as one end side of the extended portion 311 and the other end side of the extended portion 311.

In this case, the connector 313 may be connected to the resistance portion 312, elongating along the direction from one end to the other end of the extended portion 311, in such a way that the resistance portion 312 is positioned between one end and the other end of the connector 313. That is, one end of the connector 313 may be located on the one end side of the extended portion 311, and the other end of the connector 313 may be located on the other end side of the extended portion 311, with the resistance portion 312 connected therebetween.

In some examples, the connector 313 may include terminals T and a cover C that covers the terminals T in predetermined directions. In more detail, the terminals T may include a plurality of first terminals T1 that respectively output the voltage at both ends of the resistance portion 312, and the cover C covers the terminals T to prevent errors from occurring due to noise and other interference in current sensing. The cover C may be formed to surround the sides of the terminals T and allow one or both ends to remain open, exposing the first lead 310 and the terminals T to the outside.

The terminals T may be connected to an external control board, which may include a processor, such as microcontroller or microcomputer, capable of determining the current based on the voltage difference across both ends of the resistance portion 312.

In addition to the first terminals T1, the terminals T may include a second terminal T2 grounded to the external control board.

In some examples, in addition to the first lead 310, a plurality of second leads 320 that are connected to the at least one substrate 200 and spaced apart from the first lead 310 may be further included.

In this case, the first lead 310 may receive the current inflow from at least one of the plurality of second leads 320 through the substrate 200 and one end of the extended portion 311.

For example, the first lead 310 may correspond to an output terminal, while the plurality of second leads 320 may correspond to N and P terminals.

The first lead 310 and the second leads 320 may be aligned side by side on one side of the power module 10, or as shown in FIG. 1, they may be aligned on different sides of the power module 20.

The molding member 400 may encase the at least one semiconductor chip 100 and one end of the extended portion 311 of the first lead 310 among the components constituting the power module 10. Furthermore, the molding member 400 may encase a portion of the substrate 200 and provide protection to the components constituting the power module 10, ensuring electrical isolation between the interior and exterior of the power module 10.

For example, the molding member 400 may be implemented with materials such as epoxy molding compound (EMC) to protect the components constituting the power module 10 from moisture, heat, shock, etc.

As described above, the power module in various implementations of the present disclosure is advantageous in terms of reducing the interior space required for sensing the current sensing through implementation the current sensor structure on its output terminal.

With the reduction in the space required for sensing, it becomes possible to secure component layout space inside the power module, allowing for an increase in the size of each component, leading to an enhancement in the performance of the power module.

In addition, by securing space for current sensing, it becomes possible to sense current without relying on an external current sensor, thus eliminating incurrence of the cost associated with the placement of external current sensors.

Furthermore, it is possible to improve the current sensing performance by sensing the current immediately before the current is output from the power module.

Although the present disclosure has been illustrated and described in connection with specific implementations, it will be obvious to those skilled in the art that various modification and changes can be made thereto without departing from the scope of the present disclosure that is defined by the appended claims.

What is claimed is:

1. A power module comprising:
at least one semiconductor chip;
at least one substrate that supports the at least one semiconductor chip; and
a first lead comprising:
an extended portion having (i) a first end connected to the at least one substrate and (ii) a second end that protrudes outward away from the at least one substrate, and
a resistance portion disposed between the first end and the second end of the extended portion.

2. The power module of claim 1, wherein the first lead is configured to electrically connect the least one substrate to an external terminal based on the second end of the extended portion being connected to the external terminal.

3. The power module of claim 2, wherein the first lead is configured to define a current flow path from the at least one substrate to the external terminal.

4. The power module of claim 3, wherein the first lead is configured to define the current flow path in a direction from the first end of the extended portion to the second end of the extended portion via the resistance portion.

5. The power module of claim 1, wherein the extension portion extends in a first direction, and the resistance portion extends in a second direction crossing the first direction.

6. The power module of claim 5, wherein the first end and the second end of the extended portion are connected via the resistance portion.

7. The power module of claim 6, wherein the first end and the second end of the extended portion are respectively connected to opposite ends of the resistance portion in the first direction.

8. The power module of claim 1, further comprising a connector connected to the resistance portion and configured to output a voltage between ends of the resistance portion.

9. The power module of claim 8, wherein the connector is connected to the resistance portion and has a first end and a second end that are spaced apart from each other in a first direction,
wherein the connector extends along the first direction from the first end of the connector toward the second end of the extended portion, and
wherein the resistance portion is positioned between the first end of the connector and the second end of the connector.

10. The power module of claim 8, wherein the connector comprises:
a plurality of terminals, the plurality of terminals comprising a plurality of first terminals that are configured to respectively output voltages between ends of the resistance portion; and
a cover that covers the plurality of terminals in predetermined directions.

11. The power module of claim 10, wherein the plurality of terminals are connected to an external control board.

12. The power module of claim 11, wherein the plurality of terminals further comprise a second terminal that is connected to a ground of the external control board.

13. The power module of claim 1, further comprising a plurality of second leads that are connected to the at least one substrate, the plurality of second leads being separate from the first lead,
wherein the first lead is configured to receive current inflow from at least one of the plurality of second leads through the at least one substrate and the first end of the extended portion.

14. The power module of claim 1, further comprising a molding that covers the at least one semiconductor chip and the first end of the extended portion.
